(19) United States
(12) Patent Application Publication
(10) Pub. No.: US 2002/0030151 A1
(43) Pub. Date: Mar. 14, 2002

(54) Method and apparatus for instantaneous exposure control in digital imaging devices

(76) Inventor: George M. Blaszczynski, Arlington, MA (US)

Correspondence Address: HALE AND DORR, LLP, 60 STATE STREET, BOSTON, MA, 02109

(21) Appl. No.: 09/852,542

(22) Filed: May 10, 2001

Related U.S. Application Data
(60) Provisional application No. 60/231,915, filed on Sep. 11, 2000.

(51) Int. Cl. H01L 27/00

(52) U.S. Cl. 250/208.1

(57) ABSTRACT

A method and apparatus are provided for automatically controlling the exposure of an image sensing device to a light image. The image sensing device includes an array of photodetectors that generate electrons or holes from incident photons. The device also includes an overflow drain for receiving excess electrons or holes from the photodetectors to inhibit blooming. The apparatus monitors the collective current flow from the photodetectors to the overflow drain. When the current fulfills a given criterion, the apparatus limits further exposure of the photodetectors to the light image by, e.g., closing a shutter or turning off a strobe.

### RELATED APPLICATION

The present invention is based on and claims priority from Provisional Application Ser. No. 60/231,915 filed on Sep. 11, 2000 and entitled METHOD AND APPARATUS FOR INSTANTANEOUS EXPOSURE CONTROL IN DIGITAL IMAGING DEVICES.

### BACKGROUND OF THE INVENTION

1. Field of the Invention

The present invention relates generally to imaging devices and, more particularly, to a method and apparatus for instantaneous exposure control in such devices.

2. Description of Related Art

FIG. 1 is a simplified block diagram illustrating the basic components of an imaging device such as a digital camera. The device includes a lens 10, which focuses a light image onto an imaging sensor 12. The sensor 12 is typically either a Charge Coupled Device (CCD) type solid state imaging device or a Complementary Metal Oxide Semiconductor (CMOS) type solid state imaging device. The sensor 12 includes a grid of pixels or a row of pixels, each having a photodetector that converts photons that strike it into electrons or holes and a storage cell referred to as a well or a bucket that stores the electrons or holes generated by the photodetector. The wells are emptied prior to exposure. After the exposure, the electrons or holes in the wells are read out as a series of analog voltages, which are proportional to image brightness at a given pixel. In a digital camera, these voltages are converted to a series of digital numbers by an Analog to Digital (A/D) converter 14. The digital output from the converter 14 is processed by a microprocessor 16 (that may contain memory) and stored in an output memory device 18.

Sensors sometimes smear bright spots in an image in a phenomenon known as “blooming.” Blooming occurs when a pixel in the sensor receives too much light, and the well associated with the pixel overflows with electrons or holes. The extra charge can spill into the wells of neighboring less illuminated and less charged pixels, thereby spreading the size of a highlight and degrading the image. One known method of reducing blooming is to include in the sensor a mechanism to siphon off the overflow.

FIG. 2 illustrates an example of a prior art linear CCD image sensor 12 with a siphoning mechanism and an overflow drain to reduce blooming as described in U.S. Pat. No. 5,867,215. The sensor 12 includes a plurality of pixels, each comprising a photodetector 20 and a well 22 coupled to the photodetector. For illustration purposes, the sensor 12 is shown to have only four pixels. However, a typical image sensor will contain many more such pixels.

While mechanisms of this type have generally proved useful in reducing blooming, there still remains the problem of determining and controlling the period of exposure of the pixels to the light image. It is generally desirable to stop exposure as soon as the brightest areas of an image fill (or slightly overfill) their respective pixels. (The brighter areas of an image will fill up their respective pixels before other areas.) If there is overexposure, pixels for both the bright and dim areas of an image can become saturated or overfilled, and thereby contain the same information on brightness. In underexposed images, noise can significantly reduce image quality. Therefore, achieving proper exposure is critical to obtaining a good image.

In silver-halide film cameras, proper exposure is determined with an exposure sensor containing one or several photodetectors. The same method can be used in electronic cameras, but it has two drawbacks. It is not accurate because it measures average brightness while ideal exposure for an electronic camera should be determined from peak brightness. It adds unnecessary components if one considers the image sensor itself as a much better instrument for determining proper exposure.

In case of electronic still cameras, if the photographed object is well illuminated, proper exposure can be determined with the use of a test picture taken just prior the desired picture. If the object is not well illuminated a flash is needed. In that case the exposure is controlled by adjusting the duration of the flash. Since a test picture cannot be used to pre-determine the duration of the flash, a separate exposure sensor must be used.

A need exists for an improved method and apparatus for determining proper image exposure in electronic imaging devices with the use of the image sensor.

### BRIEF SUMMARY OF THE INVENTION

One object of the present invention is to provide an improved method and apparatus for automatically determining proper exposure in an electronic imaging device.

Another object of the invention is to provide a method and apparatus for instantaneously determining proper exposure in an electronic imaging device.

Yet another object of the invention is to provide an inexpensive method and apparatus for determining proper exposure in an electronic imaging device.

A further object of the invention is to provide an apparatus for determining proper exposure in an electronic imaging device that does not require additional external photodetectors and associated circuitry.

These and other objects are achieved by an inventive method and apparatus for automatically controlling the exposure of an electronic image sensing device to a light image. The electronic image sensing device in accordance with the preferred embodiment includes an array of photodetectors that generate electrons or holes from incident photons. The device also includes an overflow drain for receiving excess charge from the photodetectors to inhibit blooming. The inventive apparatus monitors the collective current flow from the photodetectors to the overflow drain. When the current satisfies a given criterion, e.g., it reaches a given magnitude, the apparatus limits further exposure of the photodetectors to the light image by, e.g., closing a shutter or turning off a strobe (or by changing the exposure of the next frame in a motion picture camera).

These and other features and advantages of the present invention will become readily apparent from the following detailed description wherein embodiments of the invention are shown and described by way of illustration of the best mode of the invention. As will be realized, the invention is capable of other and different embodiments and its several details may be capable of modifications in various respects, all without departing from the invention. Accordingly, the drawings and description are to be regarded as illustrative in nature and not in a restrictive or limiting sense with the scope of the application being indicated in the claims.

### BRIEF DESCRIPTION OF THE DRAWINGS

For a fuller understanding of the nature and objects of the present invention, reference should be made to the following detailed description taken in connection with the accompanying drawings wherein:

FIG. 1 is a schematic block diagram illustrating the basic components of a digital camera in accordance with the prior art;

FIG. 2 is a schematic block diagram of an image sensor with a mechanism for reducing blooming in accordance with the prior art;

FIG. 3 is a schematic block diagram of an image sensor with a mechanism for controlling exposure in accordance with the present invention; and

FIG. 4 is a schematic block diagram of an image sensor with a mechanism for controlling exposure in accordance with another embodiment of the present invention.

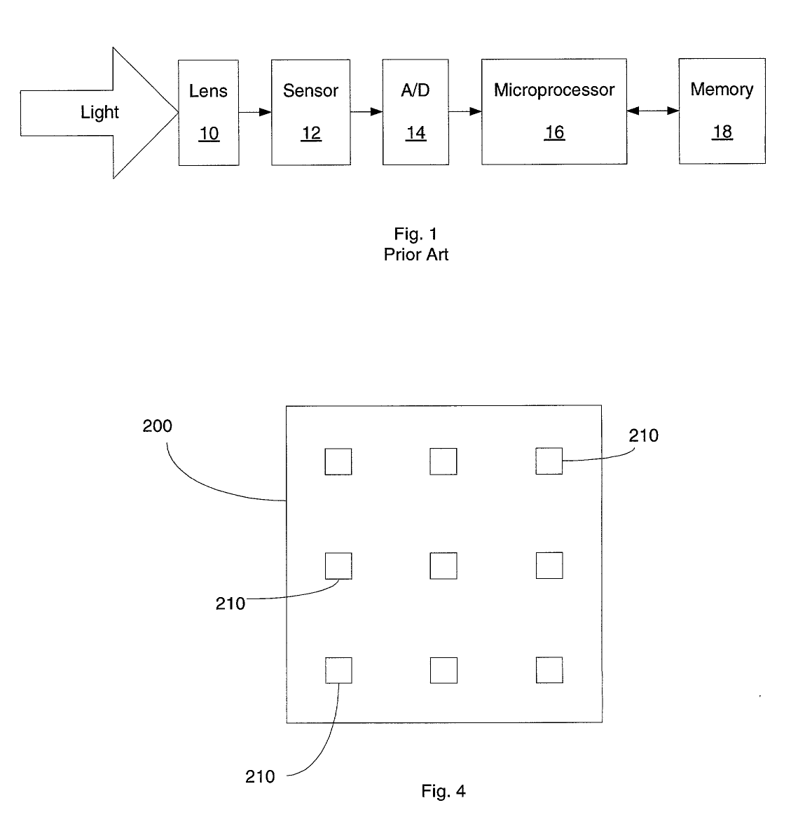

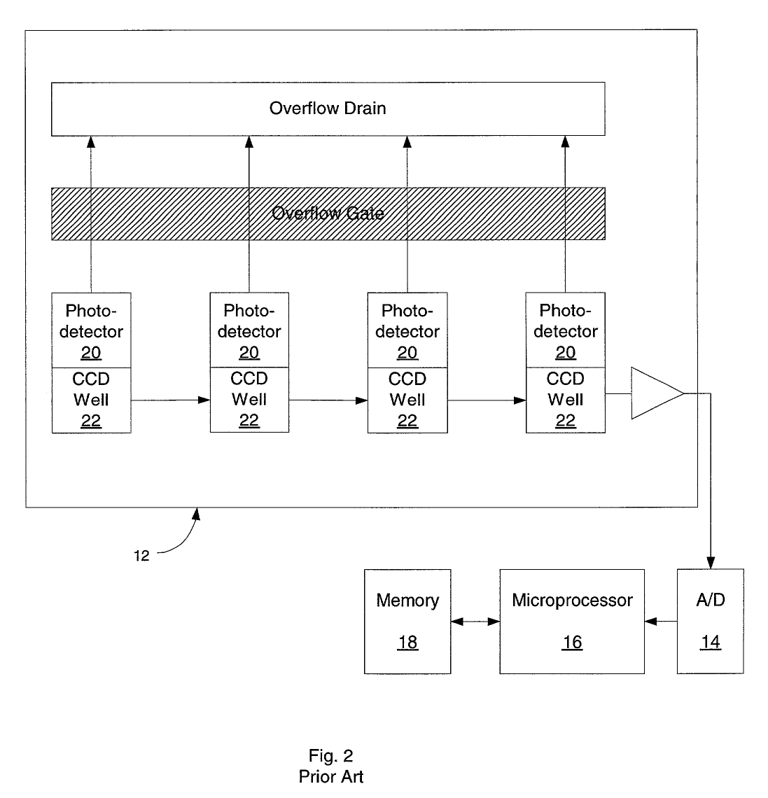

### DETAILED DESCRIPTION OF PREFERRED EMBODIMENTS

The present invention is directed to a method and apparatus for providing automatic and instantaneous exposure control in an electronic imaging device. An electronic imaging device in accordance with the invention comprises a solid state image sensor that integrates light into finite capacity potential wells such as, e.g., CMOS and CCD sensors. The invention can also be applied to sensors with additional built in circuitry such an analog-to-digital converter.

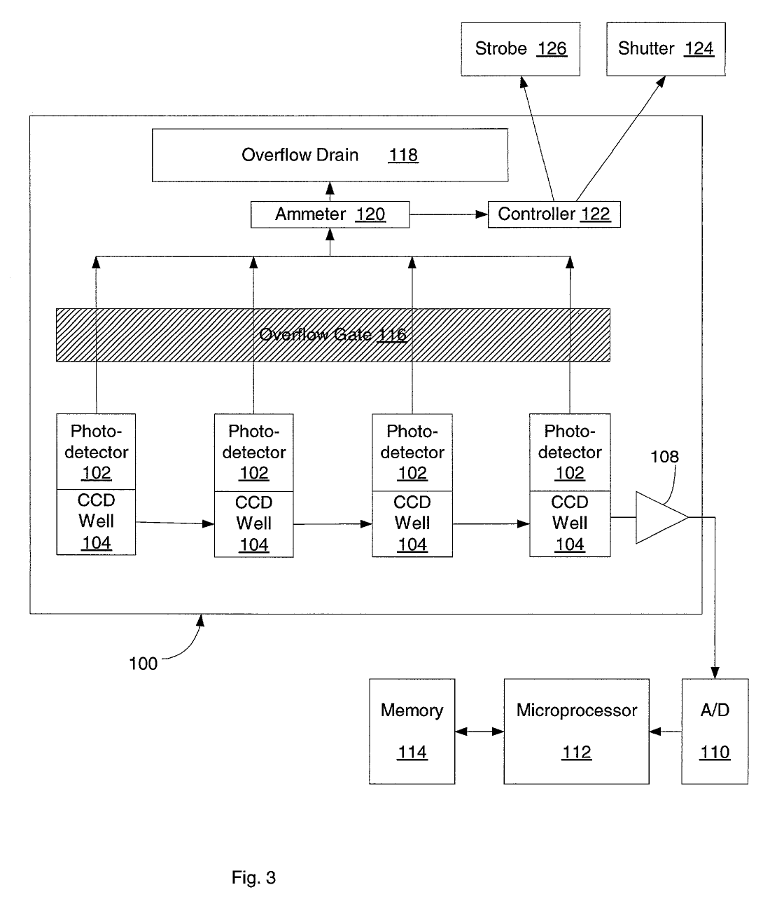

FIG. 3 illustrates an example of an imaging device with a mechanism for exposure control in accordance with the invention. For illustrative purposes, the imaging device shown in the drawing comprises a linear CCD image sensor 100. It should be noted, however, that the invention is not limited to such a sensor, and can be used in a variety of other types of image sensors including, e.g., area CCD image sensors and linear or area CMOS sensor devices.

The sensor 100 includes a plurality of pixels, each including a photodetector 102 and a CCD well 104 coupled to or integral with the photodetector. For purposes of illustration, the sensor 100 is shown to have only four pixels. However, an actual image sensor will typically contain many more such pixels, e.g., one million pixels.

The photodetectors 102 convert incident photons from a light image to electrons or holes during an exposure time interval. After the exposure, the chain of CCD wells 104 is clocked, bucket brigade style, moving the charge in each CCD well 104 to the next CCD well 104. The charge from the end CCD well 104 is amplified at 108 and usually passed to an A/D converter 110, where the analog charge voltage is converted to a digital number. This clocking is repeated until the charge in every CCD well 104, one at a time, is passed to the amplifier 108 and the A/D converter 110, resulting in a series of digital numbers, each number corresponding to the light data collected at one of the photodetectors 102. The digital signals are then processed by a microprocessor 112 and stored in an output memory device 114. (This “bucket brigade” process is generally specific to CCD sensors. As previously mentioned, it should be recognized that the inventive exposure control mechanism is not limited for use with CCD sensors, but can be used with a variety of other imaging sensors.)

To inhibit blooming (i.e., the flow of excess electrons or holes from one pixel to an adjacent less charged and less illuminated pixel), the sensor 100 includes an overflow gate 116 and overflow drain 118. The overflow gate 116 limits the charge that can accumulate in any photodetector 102 by allowing electrons or holes exceeding the capacity of a pixel to flow over the gate 116 and into the overflow drain 118, where they are removed.

In accordance with the present invention, the imaging device includes a mechanism for automated and instantaneous exposure control to inhibit the sensor 100 from being overexposed or underexposed to a light image. The inventive mechanism includes a device 120 for current and/or charge measurement and/or integration or a low pass filter. In FIG. 3, the device 120 is shown for illustrative purposes as a current sensing circuit such as, e.g., an integrated ammeter for measuring the collective current flowing from the photodetectors 102 to the overflow drain 118. The information on current is used to determine when there has been sufficient exposure. As previously mentioned, it is generally desirable to stop exposure once the brightest areas of an image fill (or slightly overfill) their respective pixels. As pixels corresponding to the brightest portions of the image overfill, the excess charge is transferred to the overflow drain 118, and the current is measured by the ammeter 120. When the current fulfills a given criterion such as, e.g., it reaches some predetermined magnitude, it is expected that there has been proper exposure and that further exposure of the sensor to the light image should be limited.

The current measured by the ammeter 120 is passed to a controller 122. The controller senses when the current has reached a predetermined magnitude, and when it does, instantly sends a control signal to an exposure control device to limit further exposure of the sensor to the light image. The exposure control device can comprise a shutter 124, e.g., a mechanical shutter at the camera lens that can be used to gate light reaching the sensor 100, or it can be an insulated gate bipolar transistor (IGBT) that shuts off current to a flash 126. Alternatively, an electronic shutter can be used to control when the sensor 100 gathers light through electronic control signals to the sensor 100. In a motion picture camera, exposure of the next frame can be increased or decreased based on controller output.

Thus, the controller 122 is operatively coupled to one or more devices for limiting exposure such as a shutter 124 or strobe 126. And when the controller 122 determines that optimal exposure of the sensor 100 has occurred (because current measured by the ammeter 120 has reached some given magnitude), it immediately limits further exposure by, e.g., turning off the strobe 126 or closing the shutter 124. The mechanism allows virtually instantaneous exposure control since the controller 122 can activate the devices 124, 126 very quickly, typically within microseconds. The mechanism also allows an inexpensive exposure control that does not require microprocessor involvement in sampling, histogramming, and thresholding the acquired images.

The inventive mechanism accordingly automatically provides proper exposure in an electronic imaging device. Since the circuitry for the exposure control mechanism is preferably integrated in an imaging sensor chip, the mechanism is relatively inexpensive.

It should be noted that the inventive mechanism is applicable to both color and black and white sensors, as well as still and motion picture cameras It should be further noted that while the electronic imaging device shown in FIG. 3 includes one channel of overflow measurement, an electronic imaging device in accordance with a further embodiment of the invention can include multiple such channels. Multiple channels can be implemented in various ways including, e.g., on a region by region basis and across color planes. These multiple channel implementations can lead to further improvements in photography, for instance, better white balance and color gain matching. They can also allow for different exposure settings or thresholds in different parts of a picture, e.g., for the perimeter vs. the center of the picture.

FIG. 4 is a simplified block diagram of an image sensor 200 including a multiple channel feature implemented on a region by region basis. The sensor 200 includes a plurality of exposure control mechanisms 210 located in different regions on the sensor. Each exposure control mechanism 210 is associated with a group of photodetectors (not shown) and includes a device (like, e.g., the ammeter 120) for monitoring the collective flow of excess electrons or holes from respective groups of photodetectors to an overflow drain. A controller (like, e.g., the controller 122) operatively coupled to the exposure control mechanisms 210 can control a shutter or strobe to limit further exposure of the photodetectors to a light image based on selective readings form the mechanisms 210.

It should be further noted that while the earlier description refers to ammeter and a threshold, an electronic imaging device in accordance with a further embodiment of the invention can use more sophisticated control logic with time varying thresholds, delayed thresholds, and/or filtered or integrated ammeter readings. For example, a few very bright pixels associated with reflections of sun from rings or watches will saturate almost immediately, so the current at the beginning of the exposure can be used to set the base threshold that can be added to the nominal threshold for a final threshold that avoids under-exposure caused by a few shiny objects.

Having described preferred embodiments of the invention, it will be apparent to one skilled in the art that changes and modifications can be made thereto without departing from the spirit and scope of the invention.

1. An apparatus for instantaneous exposure control in an image sensing device, the device comprising an array of photodetectors capable of generating electrons or holes from incident photons from a light image, a plurality of storage cells operatively coupled to or integral with the photodetectors for storing the electrons or holes generated by the photodetectors, and an overflow drain for receiving excess electrons or holes generated by the photodetectors to inhibit blooming, the apparatus comprising:
a device for determining the flow of electrons or holes from said photodetectors to said overflow drain; and
a controller operatively coupled to said device for determining the flow of electrons or holes for controlling further exposure of said photodetectors to the light image when the flow fulfills a given criterion.

2. The apparatus of claim 1 wherein the flow fulfills a given criterion when it reaches a given magnitude.

3. The apparatus of claim 1 wherein the image sensing device comprises a solid state image sensor.

4. The apparatus of claim 3 wherein the image sensor comprises a CCD sensor.

5. The apparatus of claim 3 wherein the image sensor comprises a CMOS sensor.

6. The apparatus of claim 3 wherein the image sensor comprises a color sensor.

7. The apparatus of claim 3 wherein the image sensor comprises a black and white sensor.

8. The apparatus of claim 3 wherein the image sensor comprises an area sensor.

9. The apparatus of claim 3 wherein the image sensor comprises a linear sensor.

10. The apparatus of claim 3 wherein the image sensor comprises a motion picture sensor.

11. The apparatus of claim 1 wherein the device for determining the flow of electrons or holes comprises a current sensing circuit.

12. The apparatus of claim 11 wherein said current sensing circuit comprises an external or on-chip ammeter.

13. The apparatus of claim 1 wherein the device for determining the flow of electrons or holes comprises a charge measurement device.

14. The apparatus of claim 1 wherein the device for determining the flow of electrons or holes comprises a low pass filter.

15. The apparatus of claim 1 wherein said controller is operatively coupled to a shutter for exposure control.

16. The apparatus of claim 15 wherein said shutter is a mechanical shutter.

17. The apparatus of claim 15 wherein said shutter is an electronic shutter.

18. The apparatus of claim 1 wherein said controller is operatively coupled to a flash for exposure control.

19. A method for controlling exposure of an image sensing device to a light image, the device including an array of photodetectors capable of generating electrons or holes from incident photons and an overflow drain for receiving excess electrons or holes from said photodetectors to inhibit blooming, the method comprising:
monitoring the flow of electrons or holes from said photodetectors to said overflow drain; and
limiting further exposure of said photodetectors to the light image when the flow fulfills a given criterion.

20. The method of claim 19 wherein the flow fulfills a given criterion when it reaches a given magnitude.

21. The method of claim 19 wherein monitoring the flow of electrons or holes comprises monitoring current using a current sensing circuit.

22. The method of claim 21 wherein said current sensing circuit comprises an external or on-chip ammeter.

23. The method of claim 19 wherein limiting further exposure comprises controlling an exposure control device to limit further exposure of said photodetectors to the light image.

24. The method of claim 23 wherein said exposure control device comprises a flash.

25. The method of claim 23 wherein said exposure control device comprises a shutter.

26. The method of claim 25 wherein said shutter comprises a mechanical shutter.

27. The method of claim 25 wherein said shutter comprises an electronic shutter.

28. The method of claim 19 wherein the image sensing device comprises a solid state image sensor.

29. The method of claim 28 wherein the image sensor comprises a CCD sensor.

30. The method of claim 28 wherein the image sensor comprises a CMOS sensor.

31. The method of claim 28 wherein the image sensor comprises a color sensor.

32. The method of claim 28 wherein the image sensor comprises a black and white sensor.

33. The method of claim 28 wherein the image sensor comprises an area sensor.

34. The method of claim 28 wherein the image sensor comprises a linear sensor.

35. The method of claim 28 wherein the image sensor comprises a motion picture sensor.

36. An image sensing device, comprising
an array of photodetectors for generating electrons or holes from incident photons from a light image;
a plurality of storage cells operatively coupled to or integral with the photodetectors for storing the electrons or holes generated by the photodetectors;
an overflow drain for receiving excess electrons or holes generated by the photodetectors to inhibit blooming;
a plurality of exposure control mechanisms, each mechanism associated with a group of photodetectors and comprising a device for determining the collective flow of electrons or holes from an associated group of photodetectors to said overflow drain; and
a controller operatively coupled to said devices for determining the flow of electrons or holes for controlling further exposure of said photodetectors to the light image when the flow in a given mechanism fulfills a given criterion.

37. The image sensing device of claim 36 wherein the flow fulfills a given criterion when it reaches a given magnitude.

38. A method for controlling exposure of an image sensing device to a light image, the device including an array of photodetectors capable of generating electrons or holes from incident photons and an overflow drain for receiving excess electrons or holes from said photodetectors to inhibit blooming, the method comprising:
selectively monitoring the flow of electrons or holes from groups of said photodetectors to said overflow drain; and
limiting further exposure of said photodetectors to the light image when the flow of electrons or holes from a given group of photodetectors fulfills a given criterion.

39. The method of claim 38 wherein the flow fulfills a given criterion when it reaches a given magnitude.
